(19) United States
(12) Patent Application Publication
(10) Pub. No.: US 2025/0234793 A1
(43) Pub. Date: Jul. 17, 2025

(54) SEMICONDUCTOR STRUCTURE INCLUDING MEMORY UNIT AND MANUFACTURING METHOD THEREOF

(71) Applicant: TAIWAN SEMICONDUCTOR MANUFACTURING COMPANY LTD., HSINCHU (TW)

(72) Inventors: SHIH-FENG LIU, HSINCHU CITY (TW); CHUN-YANG TSAI, HSINCHU CITY (TW); KUO-CHING HUANG, HSINCHU CITY (TW); HARRY-HAKLAY CHUANG, HSINCHU COUNTY (TW)

(21) Appl. No.: 18/409,839

(22) Filed: Jan. 11, 2024

(51) Int. Cl. H10N 70/20; H10B 63/00; H10N 70/00

(52) U.S. Cl. CPC H10N 70/24; H10B 63/00; H10N 70/063

(57) ABSTRACT

A semiconductor structure includes a first electrode, a second electrode and a dielectric layer. The second electrode is disposed over the first electrode. The dielectric layer is disposed between the first electrode and the second electrode, and is configured to store information, wherein a bandgap at a first surface of the dielectric layer facing the first electrode is greater than a bandgap at a second surface of the dielectric layer facing the second electrode. A method of manufacturing the semiconductor structure is also provided.

### BACKGROUND

The semiconductor integrated circuit industry has experienced rapid growth in the past several decades. Technological advances in semiconductor materials and design have produced increasingly compact and complex circuits. These material and design advances have been made possible as the technologies related to processing and manufacturing have also undergone technical advances. In the course of semiconductor evolution, the number of interconnected devices per unit of area has increased as the size of the smallest component that can be reliably created has decreased.

Many of the technological advances in semiconductors have occurred in the field of memory devices, and some of these memory devices involve capacitive structures. Such capacitive structures include, for example, metal-insulator-metal (MIM) capacitors. In particular, resistive random-access memory (RRAM) is one technology for non-volatile memory devices built on MIM capacitor structures. In an RRAM device, each RRAM cell (i.e., a MIM capacitor) includes a resistive material layer, the resistance of which can be adjusted to represent a logic value by switching the device between a low resistance state and a high resistance state.

One typical operation of an RRAM involves making the resistive material layer a conductor through formation of a conductive filament (i.e., a conduction path) by applying a sufficiently high electric field. Once the filament is formed, it may be reset (i.e., broken, resulting in a high resistance state) or set (i.e., re-formed, resulting in a lower resistance state). In one example, conduction through a MIM stack and the conductive filament is carried out by defects in the resistive material layer, known as oxygen vacancies (i.e., oxide bond locations from which the oxygen has been removed), which can subsequently charge and drift under an electric field. In other words, the conductive filament forms an oxygen vacancy bridge through a MIM capacitor stack. Resetting the RRAM to a high resistance state provides for the recombination of the oxygen ions with the oxygen vacancies, thereby disrupting the oxygen vacancy bridge.

One advantage of these and other MIM capacitor devices is their compatibility with CMOS fabrication processes. Current fabrication methods and structures for using MIM capacitors as RRAM devices, including those applying the formation and preservation of the filament, while suitable in many respects, can struggle to meet desired performance and reliability criteria.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic cross-sectional diagram of a semiconductor structure in accordance with some embodiments of the present disclosure.

FIG. 2 is a schematic cross-sectional diagram of a memory unit in accordance with different embodiments of the present disclosure.

FIG. 3 is a line graph showing changes of the bandgap of a dielectric layer shown in FIG. 2 along a vertical direction.

FIG. 4 is a schematic cross-sectional diagram of a memory unit in accordance with different embodiments of the present disclosure.

FIG. 5 is a line graph showing changes of the bandgap of a dielectric layer shown in FIG. 4 along a vertical direction.

FIG. 6 is a schematic cross-sectional diagram of a memory unit in accordance with different embodiments of the present disclosure.

FIG. 7 is a line graph showing changes of the bandgap of a dielectric layer shown in FIG. 6 along a vertical direction.

FIGS. 8 to 17 are schematic cross-sectional diagrams at different stages of a manufacturing method of a semiconductor structure in accordance with some embodiments of the present disclosure.

FIG. 18 is a flow diagram of a method for manufacturing a semiconductor structure in accordance with some embodiments of the present disclosure.

FIG. 19 is a flow diagram of an operation of the method shown in FIG. 18 in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, the term “source/drain region” or “source/drain regions” may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of time, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

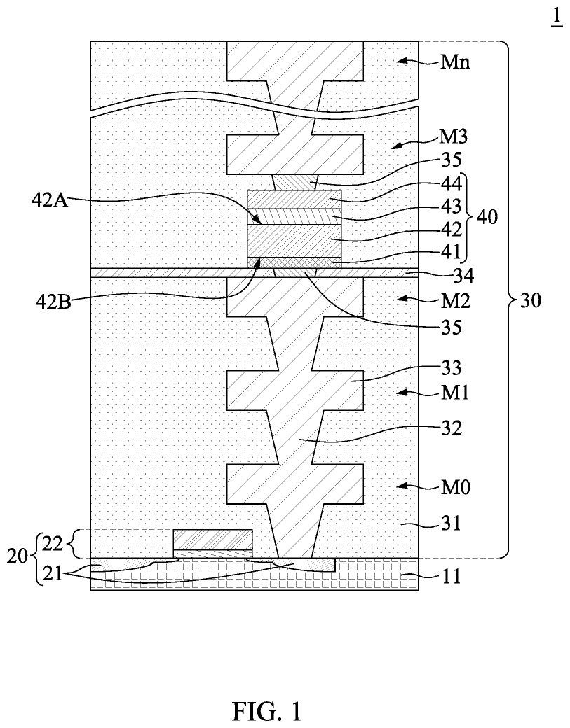

FIG. 1 is a schematic cross-sectional diagram of a semiconductor structure 1 in accordance with some embodiments of the present disclosure. The semiconductor structure 1 includes a memory unit 40 disposed in an interconnect structure 30, which is disposed over a substrate 11. In some embodiments, the memory unit 40 is electrically connected to a controller device 20 formed on the substrate 11. For a purpose of illustration, the controller device 20 is considered as a portion of the substrate 11.

In some embodiments, the substrate 11 includes a semiconductive layer and a plurality of electrical components formed on the semiconductive layer. The substrate 11 may further include an insulating layer surrounding the electrical components. The semiconductive layer may include a bulk semiconductor material, such as silicon, or other semiconductor materials, such as silicon germanium, silicon carbide, gallium arsenide, or the like. The semiconductive layer may be of a first conductivity type, e.g., a P-type semiconductive substrate (acceptor type), or a second conductivity type, e.g., an N-type semiconductive substrate (donor type).

The plurality of electrical components may be formed on the semiconductive layer following conventional methods of manufacturing semiconductors. The electrical components can be active components or devices, and may include different types or generations of devices. The electrical components can include one or more transistors, such as planar transistor, a multi-gate transistor, a gate-all-around field-effect transistor (GAAFET), a fin field-effect transistor (FinFET), a vertical transistor, a nanosheet transistor, a nanowire transistor, a bipolar junction transistor (BJT), a high-electron-mobility transistor (HEMT or HEM FET), a selector (including Ovonic threshold switching or tunneling types), or a combination thereof. For a purpose of illustration, the controller device 20 is depicted in the figures as a planar transistor 20 including source/drain structures 21 and a gate structure 22. However, the present disclosure is not limited thereto.

The interconnect structure 30 includes a plurality of conductive features (including metal via features 32 and 35 and metal line features 33) surrounded by a plurality of intermetal dielectric (IMD) layers 31. In some embodiments, the IMD layer 31 is directly over the semiconductive layer of the substrate 11. In some embodiments, the substrate 11 includes the insulating layer (not shown in the figures), and the interconnect structure 30 is formed over the insulating layer of the substrate 11. In some embodiments, the insulating layer of the substrate 11 includes a dielectric material same as that of the IMD layers 31. In some embodiments, the conductive features include tungsten (W), aluminum (Al), copper (Cu), silver (Ag), gold (Au), titanium (Ti), tantalum (Ta), ruthenium (Ru), titanium-nitride (TiN), tantalum-nitride (TaN), ruthenium nitride (RuN), tungsten nitride (WN), and alloys thereof. In some embodiments, a plurality of contacts penetrate the insulating layer to electrically connect to the electrical components.

The conductive features include a plurality of metal line layers M0 to Mn, wherein n is a positive integer greater than 1, and a plurality of metal via layers, alternately arranged between the plurality of metal line layers M0 to Mn for electrical connection between the metal line layers. The metal line layer M0 may be the first metal line layer over the substrate 11, and the metal line layer Mn may be the topmost metal line layer of the interconnect structure 30. Each of the metal line layers M0 to Mn includes a plurality of metal line features 33, and each of the metal via layers includes a plurality of metal via features 32. The conductive features may also include metal via features 35 configured to electrically connect the memory unit 40 to the metal line features 33 of adjacent metal line layers. In some embodiments, a via feature 32 is electrically connected to a source/drain structure 21 of the controller device 20.

The memory unit 40 can be a resistive random-access memory (RRAM). The memory unit 40 can include a bottom electrode 41, a dielectric layer 42, and an upper electrode 44 stacked in sequence. In some embodiments, the memory unit 40 further includes a capping layer 43 disposed between the dielectric layer 42 and the upper electrode 44. In other embodiments without the capping layer 43, the dielectric layer 42 is in direct contact with the upper electrode 44. In some embodiments, the bottom electrode 41, the dielectric layer 42, the capping layer 43 and the upper electrode 44 are sequentially disposed over one of the metal line layers of the interconnect structure 30. For example, the memory unit 40 is disposed between metal line layers M2 and M3; however, the present disclosure is not limited thereto. In some embodiments, sidewalls of the bottom electrode 41, the dielectric layer 42, the capping layer 43 and the upper electrode 44 are substantially aligned along a stacking direction of the bottom electrode 41, the dielectric layer 42, the capping layer 43 and the upper electrode 44. For a purpose of planarization, an etch stop layer 34 can be formed over the metal line layer M2, and the memory unit 40 is formed over the etch stop layer 34. In some embodiments, the bottom electrode 41 is electrically connected the metal line layer M2 through the metal via feature 35.

Conductive materials of the bottom electrode 41 and the upper electrode 44 can be same or different. The conductive materials of the bottom electrode 41 and the upper electrode 44 can be pure metal, metal-oxide, metal-nitride, or doped polysilicon. In some embodiments, the conductive material of the bottom electrode 41 includes aluminum (Al), gold (Au), platinum (Pt), ruthenium (Ru), ruthenium oxide (RuO₂), tungsten (W), tungsten nitride (WN), nickel (Ni), iridium (Ir), iridium oxide (IrO₂), molybdenum (Mo), molybdenum nitride (MoN), chromium (Cr), chromium nitride (CrN), titanium (Ti), titanium nitride (TiN), tantalum (Ta), tantalum nitride (TaN), polysilicon doped with N-type dopants (N+ poly), polysilicon doped with P-type dopants (P+ poly), or other suitable materials. The conductive material of the upper electrode 44 can include the material selected from the above list of materials of the bottom electrode 41, and the repeated description is omitted herein.

The dielectric layer 42 is a storage structure of the memory unit 40, which is configured to store information or data. The dielectric layer 42 is disposed between the bottom electrode 41 and the upper electrode 44, and oxygen vacancy bistability of the dielectric layer 42 is induced when the memory unit 40 is in operation. In other words, the dielectric layer 42 includes only oxide materials (i.e., a material composed of one or more conductive-or-semiconductive elements and oxygen). A bandgap at a first surface 42B of the dielectric layer 42 facing the bottom electrode 41 is greater than a bandgap at a second surface 42A of the dielectric layer 42 facing the upper electrode 44. In some embodiments, the first surface 42B is a bottom surface of the dielectric layer 42. In some embodiments, the second surface 42A is a top surface of the dielectric layer 42. The dielectric layer 42 can be a single-layer structure or a multi-layer structure (detailed structures are provided in different embodiments in the following description). The dielectric layer 42 may include high-k dielectric material. In some embodiments, the dielectric layer 42 includes silicon oxide (SiO₂), hafnium silicon oxide (HfₓSi₁₋ₓO₂), tantalum silicon oxide (TaₓSi₁₋ₓO₂), aluminum oxide (Al₂O₃), hafnium aluminum oxide (HfₓAl₁₋ₓO₂), tantalum aluminum oxide (TaₓAl₁₋ₓO₂), hafnium tantalum oxide (HfₓTa₁₋ₓO₂), titanium oxide (TiO₂), hafnium oxide (HfO₂), tantalum oxide (Ta₂O₅), tungsten oxide (WO₂), zirconium oxide (ZrO₂), strontium titanium oxide (SrTiO₃ or STO), or a combination thereof. In some embodiments, the dielectric layer 42 is a doped layer having an oxide material selected from the list above.

An electronegativity of a conductive or semiconductive element and a bandgap of oxide of the conductive or semiconductive element have a positive relationship. For example, a relationship of bandgaps of ZrOₓ, HfOₓ, AlOₓ and SiOₓ is ZrOₓ≅HfOₓ<AlOₓ<SiOₓ, and a relationship of electronegativity of Zr, Hfₓ, Al and Si is Zr≅Hfₓ<Al<Si. In other words, the dielectric layer 42 may have different compositions of conductive or semiconductive elements at the first surface 42B and the second surface 42A of the dielectric layer 42, and an electronegativity of the conductive or semiconductive element(s) at the first surface 42B is greater than an electronegativity of the conductive-or-semiconductive element(s) at the second surface 42A.

With many applications tending to require RRAM to operate at a lower current, a greater resistance of a dielectric material of the RRAM for data storage is required when the dielectric material is in a high resistance state. However, a change of a dielectric material with a greater resistance or bandgap results in a raise of the forming voltage during the manufacturing process. A forming voltage of a memory is a voltage applied on the memory to form filaments of the memory, and the forming voltage is much greater than an operation voltage of the memory. Such change of dielectric material results in an increase of the forming voltage, which means formation of the filaments becomes more difficult, and manufacturing cost is also increased. In addition, a switching speed of the memory can be reduced as the formation of the filaments becomes more difficult.

The present disclosure is to increase a bandgap only on a portion of a dielectric layer that is proximal or adjacent to a bottom electrode of an RRAM in order to minimize a change of forming voltage of filaments of the dielectric layer and also to enhance a process window of the RRAM. In some embodiments, the bottom electrode is an electrode of an RRAM, which applies a high electric potential when the RRAM changes from a low resistance state to a high resistance state. Since only a portion of the dielectric layer is adjusted to have a higher bandgap (or resistance), an increase of a forming voltage of filaments of the dielectric layer can be minimized, and an impact on a switching speed due to the change of the dielectric material can also be minimized. An overall performance of the RRAM can be thereby improved.

The capping layer 43 is an oxygen-affinity layer. The capping layer 43 is configured to store oxygen when the dielectric layer 42 is at a state of low resistance (e.g., when a conductive path of oxygen vacancy of the dielectric layer 42 is induced). In some embodiments, the capping layer 43 includes an oxygen-affinity material. In some embodiments, the capping layer 43 includes aluminum (Al), titanium (Ti), tantalum (Ta), hafnium (Hf), zirconium (Zr), titanium oxide (TiOₓ), zirconium oxide (ZrOₓ), germanium oxide (GeOₓ), cerium oxide (CeOₓ), or a combination thereof. In some embodiments without the capping layer 43, oxygen is stored at an interface of the dielectric layer 43 and the upper electrode 44.

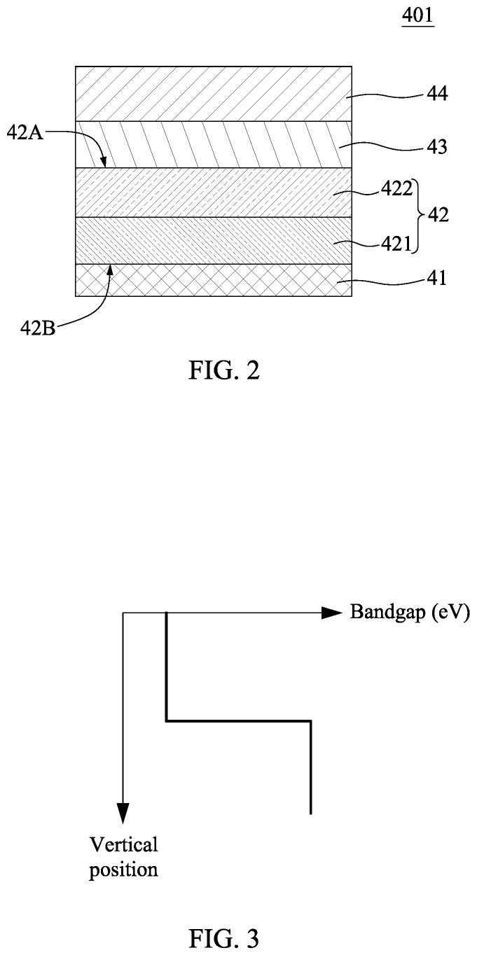

FIGS. 2, 4 and 6 are schematic cross-sectional diagrams of different memory units 401, 402 and 403, respectively, in accordance with different embodiments of the present disclosure. The memory units 401, 402 and 403 shown in FIGS. 2, 4 and 6 respectively are examples of the memory unit 40 shown in FIG. 1 in accordance with different embodiments. FIGS. 3, 5 and 7 are line graphs showing changes of the bandgaps of the dielectric layers 42 of FIGS. 2, 4 and 6 respectively along a vertical direction.

Referring to FIG. 2, in some embodiments where the dielectric layer 42 is a multi-layer structure, the dielectric layer 42 includes a first sub-layer 421 and a second sub-layer 422 over the first sub-layer 421. The first sub-layer 421 is proximal to the bottom electrode 41, and the second sub-layer 422 is proximal to the upper electrode 44. In some embodiments, the first sub-layer 421 contacts the bottom electrode 41. In some embodiments, the second sub-layer 422 contacts the capping layer 43. In some embodiments without the capping layer 43, the second sub-layer 422 contacts the upper electrode 44 (not shown). A bandgap of the first sub-layer 421 is greater than a bandgap of the second sub-layer 422. In some embodiments, a material of the first sub-layer 421 is selected from one of the following materials: silicon oxide (SiO₂), hafnium silicon oxide (HfₓSi₁₋ₓO₂), tantalum silicon oxide (TaₓSi₁₋ₓO₂), aluminum oxide (Al₂O₃), hafnium aluminum oxide (HfₓAl₁₋ₓO₂), tantalum aluminum oxide (TaₓAl₁₋ₓO₂), and hafnium tantalum oxide (HfₓTa₁₋ₓO₂). In some embodiments, a material of the second sub-layer 422 is selected from one of the following materials: titanium oxide (TiO₂), hafnium oxide (HfO₂), hafnium aluminum oxide (HfₓAl₁₋ₓO₂), tantalum oxide (Ta₂O₅), hafnium tantalum oxide (HfₓTa₁₋ₓO₂), tungsten oxide (WO₂), zirconium oxide (ZrO₂), aluminum oxide (Al₂O₃), or strontium titanium oxide (SrTiO₃, or STO).

The first sub-layer 421 and the second sub-layer 422 can be formed by different deposition operations. In some embodiments, the first sub-layer 421 and the second sub-layer 422 include different oxide materials with different bandgap values (measured in eV). FIG. 3 is the line graph showing changes of the bandgap of the dielectric layer 42 shown in FIG. 2 along a vertical direction. The line graph of the dielectric layer 42 of the memory unit 401 has a stepped configuration, and the bandgap at a lower portion of the dielectric layer 42 is greater than the bandgap at an upper portion of the dielectric layer 42.

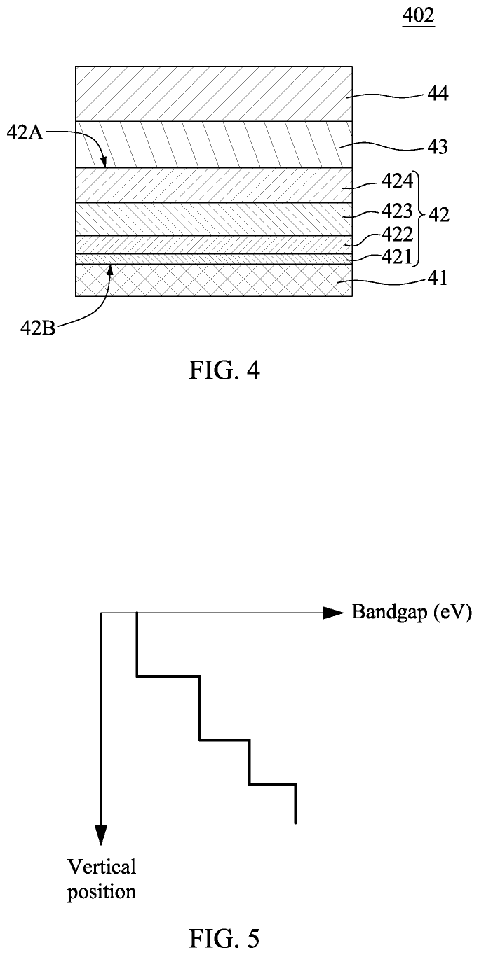

Referring to FIG. 4, the memory unit 402 is similar to the memory 401, but the dielectric layer 42 of the memory unit 402 includes additional sub-layers 421 to 424 instead of only two sub-layers 421 and 422. The sub-layers 421 to 424 are disposed in sequence from the bottom electrode 41 toward the upper electrode 44. In some embodiments, the sub-layer 421 contacts the bottom electrode 41. In some embodiments, the sub-layer 424 contacts the capping layer 43. In some embodiments without the capping layer 43, the sub-layer 424 contacts the upper electrode 44 (not shown). Similar to the configuration described above, a bandgap of the dielectric layer 42 discretely decreases at positions from the bottom electrode 41 toward the upper electrode 44. In other words, a bandgap of the sub-layer 421 is greater than a bandgap of the sub-layer 422, a bandgap of the sub-layer 422 is greater than a bandgap of the sub-layer 423, and a bandgap of the sub-layer 423 is greater than a bandgap of the sub-layer 424.

The sub-layers 421 to 424 can be formed by different deposition operations. In some embodiments, the sub-layers 421 to 424 include different oxide materials with different bandgap values (measured in eV). FIG. 5 is the line graph showing changes of the bandgap of the dielectric layer 42 shown in FIG. 3 along a vertical direction. The line graph of the dielectric layer 42 of the memory unit 401 has a multi-stepped configuration, and the bandgap of the dielectric layer 42 discretely increases at positions of greater proximity to the bottom electrode 41.

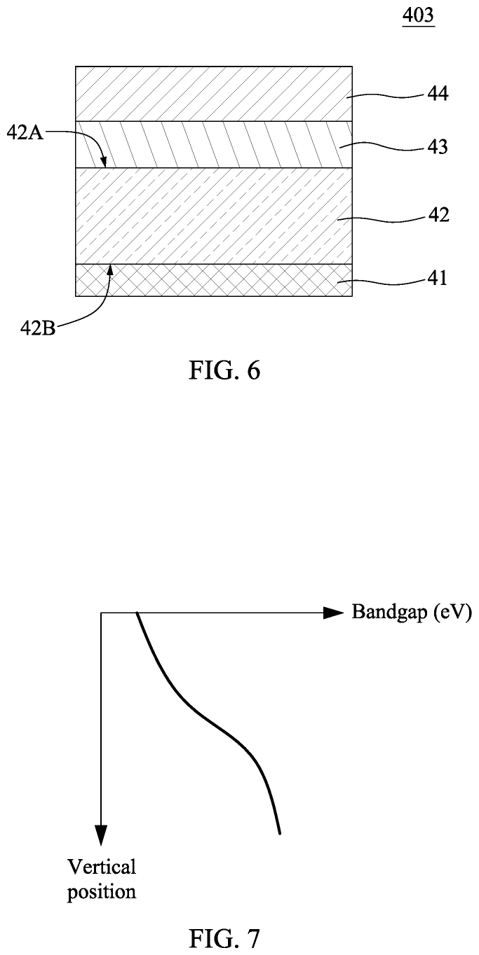

Referring to FIG. 6, the memory unit 403 is similar to the memory 401, but the dielectric layer 42 of the memory unit 403 is a single-layer structure instead of a multi-layer structure. In some embodiments, the dielectric layer 42 is formed by a single deposition. In some embodiments, a dopant is introduced during the deposition or after the deposition for a purpose of adjustment of bandgaps at different portions of the dielectric layer 42. The dielectric layer 42 can therefore have a gradient doping concentration of a conductive or semiconductive element decreasing or increasing from the bottom electrode 41 toward the upper electrode 44. For example, a deposition of ZrO₂ is performed to form the dielectric layer 42, and Si is introduced during the deposition, wherein an amount of Si introduced decreases along with a time duration of the deposition. Therefore, a concentration of Si gradually decreases at positions from the bottom electrode 41 toward the upper electrode 44, and the bandgap of the dielectric layer 42 continuously decreases at positions from the first surface 42B toward the second surface 42A. For another example, a deposition of Al₂O₃ is performed to form the dielectric layer 42, and Hf is introduced during the deposition. In some embodiments, an amount of Hf introduced increases along with a time duration of the deposition, and a concentration of Hf gradually increases at positions from the bottom electrode 41 toward the upper electrode 44. Therefore, the bandgap of the dielectric layer 42 continuously decreases at positions from the first surface 42B toward the second surface 42A. In some embodiments, the introduction of Hf begins after the deposition begins. A concentration of Hf at the first surface 42B can be substantially zero, and a concentration of Hf at the second surface 42A is greater than that at the first surface 42B. Therefore, the bandgap of the dielectric layer 42 decreases at positions from the first surface 42B toward the second surface 42A.

FIG. 6 is the line graph showing changes of the bandgap of the dielectric layer 42 shown in FIG. 5 along a vertical direction. The line graph of the dielectric layer 42 of the memory unit 401 has a configuration of a smooth curve, and the bandgap of the dielectric layer 42 continuously or smoothly increases at positions of greater proximity to the bottom electrode 41. The dopant can be introduced at the beginning, middle, or end of the deposition, and a configuration of a bandgap line graph thereof may still be a curved configuration but not a stepped configuration with a sharp change of bandgap.

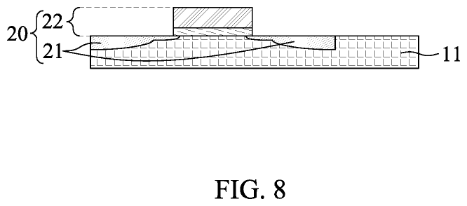

FIGS. 8 to 17 are schematic cross-sectional diagrams at different stages of a manufacturing method of the semiconductor structure 1 in accordance with some embodiments of the present disclosure.

Referring to FIG. 8, a substrate 11 including a controller device 20 (e.g., a BJT, a HEMT, a selector, or a combination thereof) formed thereon is received, provided or formed. The controller device can be formed following conventional methods of manufacturing semiconductors, and the detailed description is omitted herein.

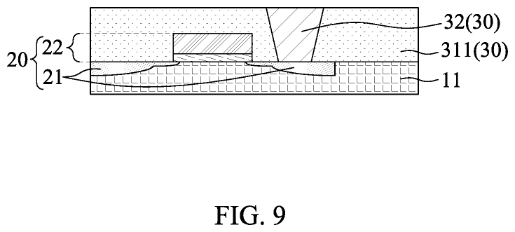

Referring to FIG. 9, an IMD layer 311 of an interconnect structure 30 is formed over the substrate 11, and a metal via feature 32 is formed penetrating the IMD layer 311 to electrically connect to the controller device 20 (e.g., a source/drain structure 21 of the controller device 20). The IMD layer 311 is one of the IMD layers 31 shown in FIG. 1. In some embodiments, the substrate 11 may include an insulating layer covering the controller device 20. In some embodiments, an interface between the IMD layer 311 and the insulating layer may not be observable. For a purpose of illustration and simplicity of the drawings, the insulating layer is omitted from the figures.

The IMD layer 311 may include oxide, nitride, oxynitride, low-k dielectric materials, or a combination thereof. The IMD layer 311 may be formed using a suitable process, such as atomic layer deposition (ALD), chemical vapor deposition (CVD), physical vapor deposition (PVD), -plasma-enhanced PVD (PEPVD), -plasma-enhanced ALD (PEALD), or combinations thereof. A patterning operation may be performed on the IMD layer 311 prior to the formation of the metal via feature 32 to remove a portion of the IMD layer 311. A suitable process may be applied to form the metal via feature 32, such as deposition, electroplating, electro-less plating, or another suitable process.

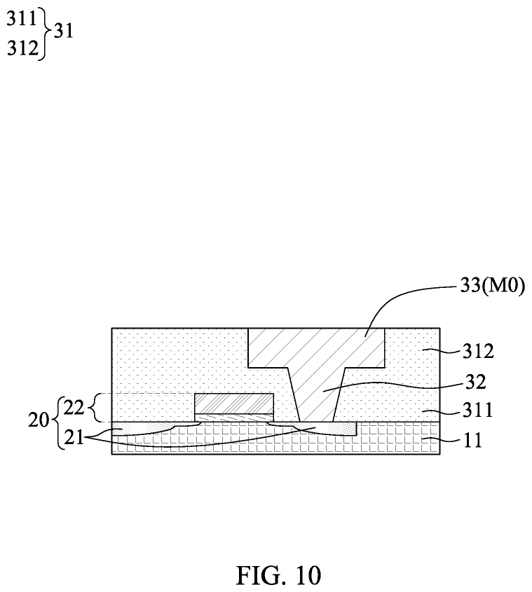

Referring to FIG. 10, an IMD layer 312 (i.e., one of the IMD layers 31 shown in FIG. 1) is formed over the IMD layer 311, and a metal line feature 33 is formed in the IMD layer 312 to electrically connect to the metal via feature 32. The metal line feature 33 can be one of the metal line features 33 disposed in the metal line layer M0, which is a first metal line layer over the controller device 20. In some embodiments, a configuration or a pattern of the metal line feature 33 is defined by a patterning operation. In some embodiments, the IMD layer 312 is formed after the formation of the metal line feature 33.

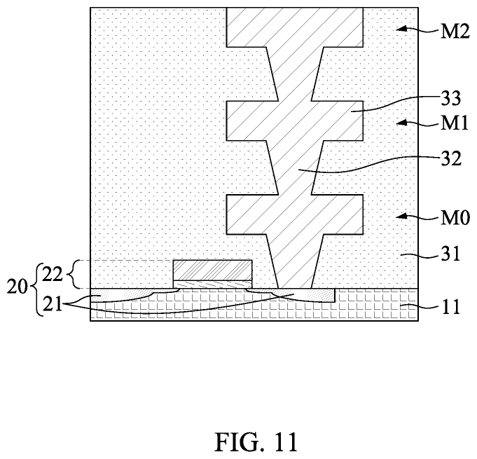

Referring to FIG. 11, operations as depicted in FIGS. 9 and 10 are repeated to form a plurality of metal line layers (e.g., M1 and M2) and a plurality of metal via layers alternately arranged between the metal line layers. For a purpose of efficiency, a memory unit 40 to be formed in subsequent processing is disposed over a metal line layer close to the controller device 20. For a purpose of the process facilitation, the memory unit 40 is a couple metal line layers away from the controller device 20. In some embodiments, the memory unit 40 is formed over one of the metal line layers M1 to M6. In an exemplary embodiment of the semiconductor structure 1, the memory unit 40 is disposed over the metal line layer M2.

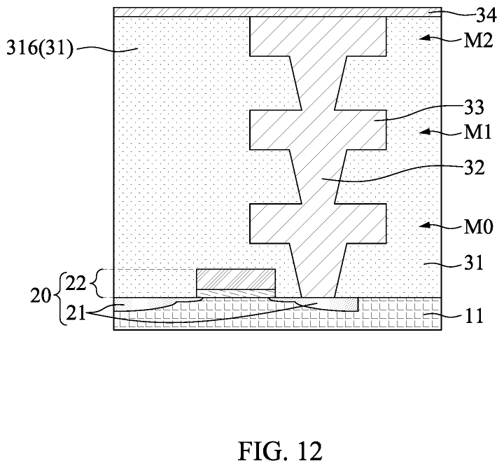

Referring to FIG. 12, an etch stop layer 34 is formed over the metal line layer M2. In some embodiments, the metal line feature 33 of the metal line layer M2 is surrounded by an IMD layer 316, which is one of the IMD layers 31. In some embodiments, the etch stop layer 34 covers the IMD layer 316 and the metal line layer M2. The etch stop layer 34 can provide an etching selectivity of patterning operations performed during the formation of the memory unit 40. The etch stop layer 34 may also provide a planar surface for a better process platform of the formation of the memory unit 40. In some embodiments, the etch stop layer 34 is referred to as a hardmask layer, a mask layer or a base layer.

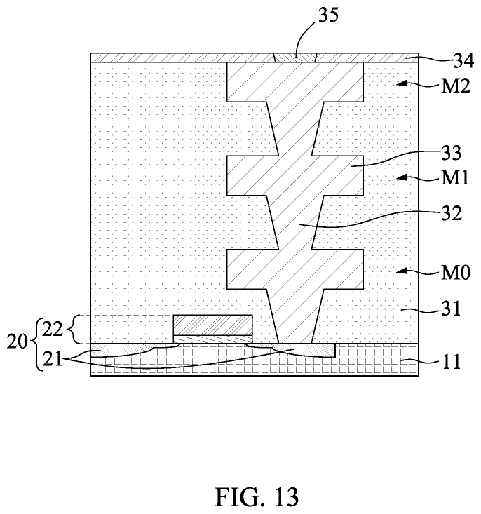

Referring to FIG. 13, a metal via feature 35 for electrical connection to the memory unit 40 is formed in the etch stop layer 34. A patterning operation followed by a deposition is performed to form the metal via feature 35. In some embodiments, the metal via feature 35 contacts a metal line feature 33 in the metal line layer M2. In some embodiments, the metal via feature 35 is electrically connected to the controller device 20. In some embodiments, the metal via feature 35 is electrically connected to the source/drain structure 21 of the controller device 20. In some embodiments, a thickness of the metal via feature 35 is defined by a thickness of the etch stop layer 34. The thickness of the metal via feature 35 can be different from a thickness of a metal via feature 32, for a purpose of electrical connection of adjacent metal line layers. In some embodiments, the thickness of the metal via feature 35 is less than the thickness of the metal via feature 32. In some embodiments, a top surface of the metal via feature 35 is substantially aligned with a top surface of the etch top layer 34. In some embodiments, the top surface of the metal via feature 35 is substantially coplanar with the top surface of the etch top layer 34.

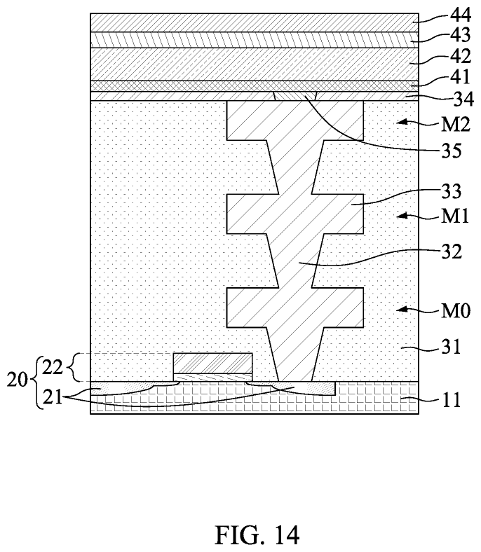

Referring to FIG. 14, a bottom electrode 41, a dielectric layer 42, a capping layer 43, and an upper electrode 44 are sequentially formed over the etch stop layer 34. In some embodiments, the bottom electrode 41 contacts the metal via feature 35. In some embodiments, the bottom electrode 41 is electrically connected to the controller device 20 through the metal via feature 35. In some embodiments, the bottom electrode 41 is electrically connected to the source/drain structure 21 of the controller device 20. In some embodiments, the dielectric layer 42 contacts the bottom electrode 41. In some embodiments, the capping layer 43 contacts the dielectric layer 42. In some embodiments, the upper electrode 44 contacts the capping layer 43. Thicknesses of the bottom electrode 41, the dielectric layer 42, the capping layer 43, and the upper electrode 44 can be adjusted according to specifications or requirements of different applications, and are not limited herein. In some embodiments, the dielectric layer 42 can be a single-layer structure or a multi-layer structure as illustrated depending on different processing configurations, and repetition is omitted herein.

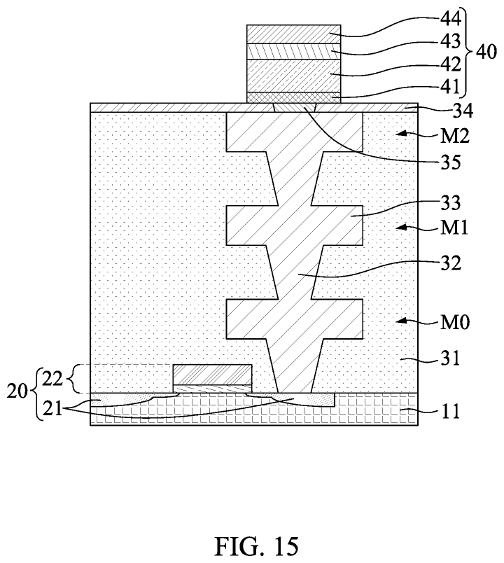

Referring to FIG. 15, a patterning operation is performed on the bottom electrode 41, the dielectric layer 42, the capping layer 43, and the upper electrode 44 to form the memory unit 40. The patterning operation can include one or more etching steps so as to utilize better etching selectivities and achieve a better patterning result. In some embodiments, the patterning operation stops on the etch stop layer 34 due to the etching selectivity. In some embodiments, sidewalls of the bottom electrode 41, the dielectric layer 42, the capping layer 43, and the upper electrode 44 are substantially aligned along a stacking direction of the bottom electrode 41, the dielectric layer 42, the capping layer 43, and the upper electrode 44. In some embodiments, the memory unit 40 overlaps at least a portion of a metal line feature 33 in the metal line layer M2. In some embodiments, the metal via feature 35 is within an area of a vertical projection of the memory unit 40.

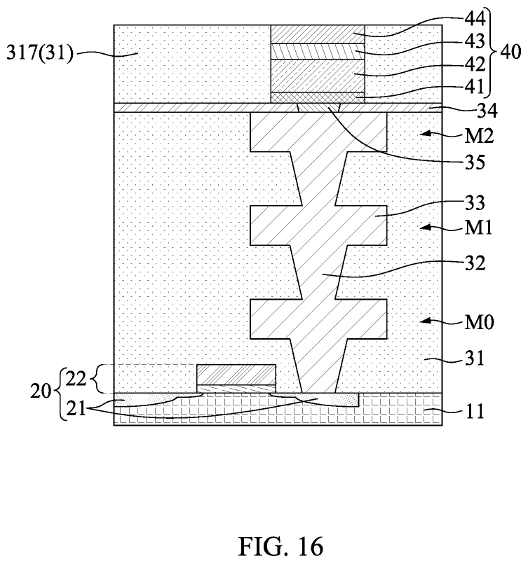

Referring to FIG. 16, an IMD layer 317, which is one of the IMD layers 31, is formed surrounding the memory unit 40 over the etch stop layer 34. In some embodiments, the IMD layer 317 is formed by a deposition followed by a planarization, such as etching, chemical mechanical polishing (CMP), a combination thereof or the like. In some embodiments, a top surface of the upper electrode 44 is substantially aligned with a top surface of the IMD layer 317. In some embodiments, the top surface of the upper electrode 44 is substantially coplanar with the top surface of the IMD layer 317.

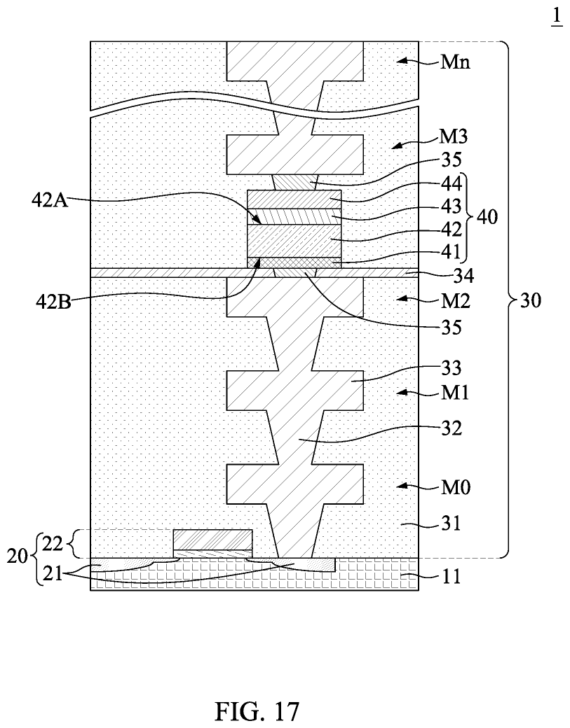

Referring to FIG. 17, operations as depicted in FIGS. 9 and 10 are repeated to form a plurality of metal line layers (e.g., M3 and Mn), a plurality of metal via layers alternately arranged between the metal line layers, and a plurality of IMD layers 31 surrounding metal line features and metal via features over the memory unit 40. The semiconductor structure 1 is thereby formed.

To conclude the processes of different embodiments as described above, a method 700 is provided.

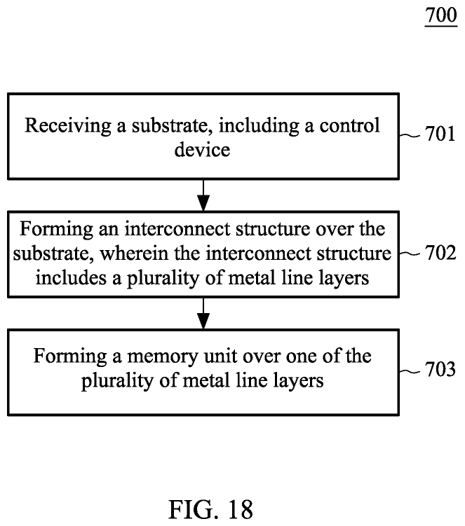

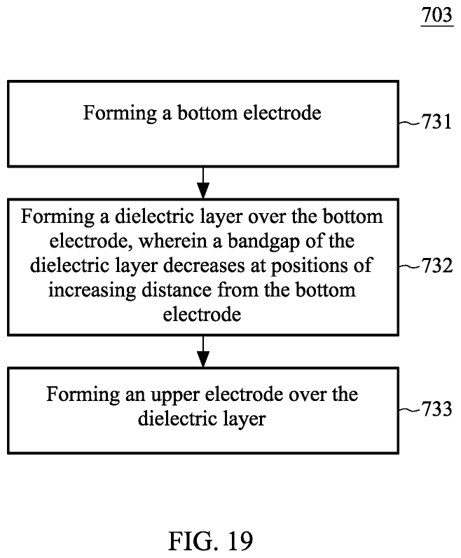

FIG. 18 is a flow diagram of the method 700 for manufacturing a semiconductor structure in accordance with some embodiments of the present disclosure, and FIG. 19 is a flow diagram of an operation of the method 700 for manufacturing a memory unit in accordance with some embodiments of the present disclosure. The method 700 includes a number of operations (701, 702 and 703), which may include a number of steps (731, 732 and 733), and the description and illustration are not deemed as a limitation to the sequence of the operations. In the operation 701, a substrate is received, wherein the substrate includes a controller device. In the operation 702, an interconnect structure is formed over the substrate, wherein the interconnect structure includes a plurality of metal line layers. In the operation 703, a memory unit is formed over one of the plurality of metal line layers, wherein the operation 703 includes steps 731 to 733. In the step 731, a bottom electrode is formed. In the step 732, a dielectric layer (such as a high-k dielectric layer) is formed over the bottom electrode, wherein a bandgap of the dielectric layer decreases at positions of increasing distance from the bottom electrode. In the step 733, an upper electrode is formed over the dielectric layer.

The operations of the method 700 can be rearranged or otherwise modified within the scope of the various aspects. In some embodiments, additional processes are provided before, during, and after the method 700, and some other processes are only briefly described herein. Thus, other implementations are possible within the scope of the various aspects described herein.

In accordance with some embodiments of the disclosure, a semiconductor structure is provided. The semiconductor structure includes a first electrode, a second electrode and a dielectric layer. The second electrode is disposed over the first electrode. The dielectric layer is disposed between the first electrode and the second electrode, and is configured to store information, wherein a bandgap at a first surface of the dielectric layer facing the first electrode is greater than a bandgap at a second surface of the dielectric layer facing the second electrode.

In accordance with some embodiments of the disclosure, a semiconductor structure is provided. The semiconductor structure includes a substrate, an interconnect structure, and a memory unit. The interconnect structure is disposed over the substrate. The memory unit is disposed in the interconnect structure, and comprises: a bottom electrode, an upper electrode, and high-k dielectric layer. The upper electrode is disposed over the bottom electrode. The high-k dielectric layer is disposed between the bottom electrode and the upper electrode, wherein a bandgap at a first surface of the high-k dielectric layer facing the bottom electrode is greater than a bandgap at a second surface of the high-k dielectric layer facing the upper electrode.

In accordance with some embodiments of the disclosure, a method for manufacturing a semiconductor structure is provided. The method may include several operations and steps. A substrate is received, and the substrate includes a controller device. An interconnect structure is formed over the substrate, wherein the interconnect structure includes a plurality of metal line layers. A memory unit is formed over one of the plurality of metal line layers, wherein the formation of the memory unit includes: forming a bottom electrode; forming a dielectric layer over the bottom electrode; and forming an upper electrode over the dielectric layer, wherein a bandgap of the dielectric layer decreases at positions of increasing distance from the bottom electrode.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a first electrode;
a second electrode, disposed over the first electrode; and
a dielectric layer, disposed between the first electrode and the second electrode, and configured to store information, wherein a bandgap at a first surface of the dielectric layer facing the first electrode is greater than a bandgap at a second surface of the dielectric layer facing the second electrode.

2. The semiconductor structure of claim 1, wherein the dielectric layer is a multi-layer structure and includes a first sub-layer proximal to the first electrode and a second sub-layer proximal to the second electrode, and a bandgap of the first sub-layer is greater than a bandgap of the second sub-layer.

3. The semiconductor structure of claim 2, wherein the dielectric layer further includes a third sub-layer disposed between the first sub-layer and the second sub-layer, wherein a bandgap of the third sub-layer is greater than the bandgap of the second sub-layer and less than the bandgap of the first sub-layer.

4. The semiconductor structure of claim 1, wherein the bandgap of the dielectric layer discretely decreases at positions from the first electrode toward the second electrode.

5. The semiconductor structure of claim 1, wherein the bandgap of the dielectric layer continuously decreases at positions from the first electrode toward the second electrode.

6. The semiconductor structure of claim 1, further comprising:
a capping layer, disposed between the dielectric layer and the second electrode.

7. The semiconductor structure of claim 6, wherein the capping layer includes aluminum, titanium, tantalum, hafnium, zirconium, titanium oxide, zirconium oxide, germanium oxide, cerium oxide, or a combination thereof.

8. A semiconductor structure, comprising:
a substrate;
an interconnect structure, disposed over the substrate; and
a memory unit, disposed in the interconnect structure, and comprising:
a bottom electrode;
an upper electrode, disposed over the bottom electrode; and
a high-k dielectric layer, disposed between the bottom electrode and the upper electrode, wherein a bandgap at a first surface of the high-k dielectric layer facing the bottom electrode is greater than a bandgap at a second surface of the high-k dielectric layer facing the upper electrode.

9. The semiconductor structure of claim 8, wherein the memory unit is disposed over a metal line layer or a metal via layer of the interconnect structure over the substrate.

10. The semiconductor structure of claim 8, wherein the high-k dielectric layer is a multi-layer structure and includes a first sub-layer proximal to the first electrode and a second sub-layer proximal to the second electrode, and a bandgap of the first sub-layer is greater than a bandgap of the second sub-layer.

11. The semiconductor structure of claim 10, wherein the second sub-layer includes titanium oxide (TiO₂), hafnium oxide (HfO₂), hafnium aluminum oxide (HfₓAl₁₋ₓO₂), tantalum oxide (Ta₂O₅), hafnium tantalum oxide (HfₓTa₁₋ₓO₂), tungsten oxide (WO₂), zirconium oxide (ZrO₂), aluminum oxide (Al₂O₃), or strontium titanium oxide (SrTiO₃ or STO).

12. The semiconductor structure of claim 10, wherein the first sub-layer includes silicon oxide (SiO₂), hafnium silicon oxide (HfₓSi₁₋ₓO₂), tantalum silicon oxide (TaₓSi₁₋ₓO₂), aluminum oxide (Al₂O₃), hafnium aluminum oxide (HfₓAl₁₋ₓO₂), tantalum aluminum oxide (TaₓAl₁₋ₓO₂), or hafnium tantalum oxide (HfₓTa₁₋ₓO₂).

13. The semiconductor structure of claim 8, wherein the memory unit further comprises:
a capping layer, disposed between the high-k dielectric layer and the upper electrode, wherein the capping layer includes an oxide affinity material.

14. The semiconductor structure of claim 8, wherein the memory unit is surrounded by a low-k dielectric material.

15. The semiconductor structure of claim 8, wherein the bottom electrode of the memory unit is electrically connected to a metal line feature of the interconnect structure through a metal via feature.

16. The semiconductor structure of claim 8, wherein the memory unit is disposed over a metal line feature of the interconnect structure, and the interconnect structure further comprises an etch stop layer between the memory unit and the metal line feature.

17. A method of manufacturing a semiconductor structure, comprising:
receiving a substrate, including a controller device;
forming an interconnect structure over the substrate, wherein the interconnect structure includes a plurality of metal line layers; and
forming a memory unit over one of the plurality of metal line layers, wherein the formation of the memory unit comprises:
forming a bottom electrode;
forming a dielectric layer over the bottom electrode, wherein a bandgap of the dielectric layer decreases at positions of increasing distance from the bottom electrode; and
forming an upper electrode over the dielectric layer.

18. The method of claim 17, wherein the formation of the memory unit further comprises:
patterning the upper electrode, the dielectric layer, and the bottom electrode, wherein sidewalls of the upper electrode, the dielectric layer, and the bottom electrode are substantially aligned after the patterning.

19. The method of claim 17, wherein the formation of the dielectric layer comprises a plurality of depositions of different dielectric materials.

20. The method of claim 17, wherein the formation of the dielectric layer comprises:
performing a deposition of an oxide material, wherein the oxide material includes a first conductive-or-semiconductive element,
wherein the performing of the deposition further comprises introducing a second conductive-or-semiconductive element having an electronegativity greater than that of the first conductive-or-semiconductive element at the beginning of the deposition of the oxide material.
